(19) United States
(12) Patent Application Publication
(10) Pub. No.: US 2026/0239531 A1
(43) Pub. Date: Aug. 13, 2026

(54) PRINTED CIRCUIT BOARD, MANUFACTURING METHOD THEREOF, AND ELECTRONIC COMPONENT PACKAGE INCLUDING THE SAME

(71) Applicant: SAMSUNG ELECTRO-MECHANICS CO., LTD., Suwon-si (KR)

(72) Inventor: Sang-Min Lee, Suwon-si (KR)

(73) Assignee: SAMSUNG ELECTRO-MECHANICS CO., LTD., Suwon-si (KR)

(21) Appl. No.: 19/271,470

(22) Filed: Jul. 16, 2025

(30) Foreign Application Priority Data
Feb. 11, 2025 (KR) 10-2025-0017419

(51) Int. Cl. H05K 1/11; H05K 1/18; H05K 3/10; H05K 3/40

(52) U.S. Cl. CPC H05K 1/111; H05K 1/115; H05K 1/181; H05K 3/10; H05K 3/4007; H05K 2201/09036

(57) ABSTRACT

A printed circuit board according to an embodiment may include an inner insulating layer interposed between a first outer insulating layer and a second outer insulating layer, a connection pad and a circuit wiring on the first outer insulating layer, the second outer insulating layer, and the inner insulating layer, a connection via penetrating one of the second outer insulating layer and the inner insulating layer to connect the connection pads on different insulating layers, and a bump via penetrating the first outer insulating layer. The first outer insulating layer may include a cavity in which a portion of a surface thereof is recessed, and an end surface of the bump via may be exposed through the bottom surface of the cavity.

### CROSS-REFERENCE TO RELATED APPLICATION

This application claims priority to and the benefit of Korean Patent Application No. 10-2025-0017419 filed with the Korean Intellectual Property Office on Feb. 11, 2025, the entire contents of which are incorporated herein by reference.

### BACKGROUND

### (a) Technical Field of the Invention

The present disclosure relates to a printed circuit board, a manufacturing method thereof, and an electronic component package including the same.

### (b) Description of the Related Art

Demand for high-performance logic semiconductors is increasing in technical fields such as AI and automatic driving vehicles, and package technology is also changing.

For the package of high-performance logic semiconductors, a printed circuit board with a thick core and an insulating layer such as an Ajinomoto Build-up Film (ABF) was used, but it is necessary to reduce the thickness of the printed circuit board to make electronic devices thin.

Although the thickness of a printed circuit board may be reduced by using a coreless substrate, the coreless substrate is weak to warpage due to the difference in the thermal expansion coefficient with the semiconductor chip. In particular, when the bump pitch for connection with the semiconductor chip decreases, a bridge may occur between adjacent bumps.

### SUMMARY

Embodiments of the present disclosure attempt to provide a printed circuit board, a manufacturing method thereof, and an electronic component package including the same capable of reducing a bridge between bumps.

In addition, embodiments of the present disclosure attempt to provide a printed circuit board, a manufacturing method thereof, and an electronic component package including the same capable of reducing mechanical failures such as fall or breakaway of a bump even if warpage occurs.

However, the problem to be solved by embodiments of the present disclosure is not limited to the above-described problems and can be variously extended within the scope of the technical concept included in the present disclosure.

According to an embodiment, a printed circuit board may include a first outer insulating layer, a second outer insulating layer, an inner insulating layer interposing the first outer insulating layer and the second outer insulating layer, a connection pad and a circuit wiring, where the connection pad and the circuit wiring are disposed on the first outer insulating layer, the second outer insulating layer, and the inner insulating layer, a connection via penetrating one insulating layer among the second outer insulating layer and the inner insulating layer to connect the connection pad disposed on the first outer insulating layer, the second outer insulating layer, and the inner insulating layer, and a bump via penetrating the first outer insulating layer. The first outer insulating layer may include a cavity that is recessed into a first portion of a surface of the first outer insulating layer, and an end surface of the bump via may be extended from a first surface of the cavity.

The surface treatment layer may be disposed on the end surface of the bump via.

The surface conductive layer may be disposed on the end surface of the bump via and the first surface of the cavity, and the surface treatment layer may be disposed on the surface conductive layer.

The surface conductive layer may include a metal having an etch selectivity with respect to the bump via.

The first outer insulating layer may further include a trench that is recessed into a second portion of the surface of the first outer insulating layer.

A depth of the trench may be greater than a depth of the cavity.

A mounting pad may be buried in the first outer insulating layer, where a surface of the mounting pad may extend from the surface of the first outer insulating layer.

A surface conductive layer may be between the surface treatment layer and the end surface of the bump via. The connection pad and the surface conductive layer include the same material.

According to another embodiment, a printed circuit board may include an insulating layer having a cavity that is recessed into a portion of a surface of the insulating layer, a bump via penetrating the insulating layer, wherein an end surface of the bump via extends from a surface of the cavity, and a surface treatment layer on the end surface of the bump via.

According to an embodiment, a manufacturing method of a printed circuit board may include forming a first conductive pattern defining a cavity on a carrier. A first outer insulating layer may be formed on the carrier to cover the first conductive pattern. A bump via penetrating the first outer insulating layer to connect the first conductive pattern and a first connection pad extending from the bump via onto the first outer insulating layer may be formed. A build-up process may be applied on the first outer insulating layer. Thereafter, the carrier may be removed, and at least a portion of the first conductive pattern may be removed.

The removing of the at least the portion of the first conductive pattern may include forming the cavity exposing an end surface of the bump via.

A surface treatment layer may be formed on the end surface of the bump via exposed through a surface of the cavity.

The removing of the at least the portion of the first conductive pattern may include reducing a thickness of the first conductive pattern to form a surface conductive layer remaining in the cavity.

A surface treatment layer may be formed on the surface conductive layer.

The forming of the first conductive pattern may further include forming a second conductive pattern defining a trench. In this case, the removing of the at least the portion of the first conductive pattern may include removing the second conductive pattern.

The forming of the first conductive pattern may further include forming a mounting pad on the carrier.

The applying of the build-up process on the first outer insulating layer may include forming an inner insulating layer on the first outer insulating layer to cover the first connection pad. A first connection via penetrating the inner insulating layer to connect the first connection pad and a second connection pad extending from the first connection via onto the first outer insulating layer may be formed. A second outer insulating layer may be formed on the inner insulating layer to cover the second connection pad. A second connection via penetrating the second outer insulating layer to connect the second connection pad and a third connection pad extending from the second connection via onto the inner insulating layer may be formed.

According to an embodiment, an electronic component package may include a printed circuit board including a first outer insulating layer, a second outer insulating layer, an inner insulating layer interposing the first outer insulating layer and the second outer insulating layer, a connection pad and a circuit wiring, where the connection pad and the circuit wiring are disposed on the first outer insulating layer, the second outer insulating layer, and the inner insulating layer, a connection via penetrating one insulating layer among the second outer insulating layer and the inner insulating layer to connect the connection pad disposed on the first outer insulating layer, the second outer insulating layer, and the inner insulating layer, a cavity that is recessed into a portion of a surface of the first outer insulating layer, a bump via penetrating the first outer insulating layer so that an end surface of the bump via extends from a surface of the cavity, and a surface treatment layer on the end surface of the bump via. In addition, the electronic component package may include a semiconductor chip comprising an outer connection pad on one surface of the semiconductor chip, and a connection member, where at least a portion of the connection member is disposed within the cavity and the connection member connects the end surface of the bump via to the outer connection pad of the semiconductor chip.

A surface conductive layer may interpose the end surface of the bump via and the surface treatment layer, and extend onto a surface of the cavity.

The surface conductive layer may include a metal having an etch selectivity with respect to the bump via.

According to an embodiments, by forming a bump for connection with an electronic component such as a semiconductor chip in the cavity of the insulating layer, it is possible to reduce the occurrence of bridges between adjacent bumps by connection members such as solder.

In addition, a bump for connection with a semiconductor chip may protrude small over the insulating layer. Therefore, mechanical failures such as fall or breakaway of a bump may be reduced.

However, it is obvious that the effects of the embodiments are not limited to the above-described effects and may be variously extended without departing from the concept and scope of the present disclosure.

### BRIEF DESCRIPTION OF THE DRAWINGS

FIG. 1 is a cross-sectional view illustrating a printed circuit board and an electronic component including the same according to an embodiment.

FIG. 2 is a cross-sectional view illustrating a portion of the printed circuit board according to an embodiment.

FIG. 3 is a cross-sectional view illustrating a portion of a printed circuit board according to another embodiment.

FIGS. 4 to 10 are cross-sectional views illustrating a manufacturing method of a printed circuit board according to an embodiment.

FIGS. 11 to 12 are cross-sectional views illustrating a manufacturing method of a printed circuit board according to another embodiment.

FIG. 13 is a cross-sectional view illustrating a manufacturing method of a printed circuit board according to yet another embodiment.

### DETAILED DESCRIPTION

Hereinafter, various embodiments of the present disclosure will be described in detail so that a person of ordinary skill in the technical field to which the present disclosure belongs can easily implement it with reference to the accompanying drawings. The present disclosure may be implemented in various different forms and is not limited to the embodiments described herein.

In order to clearly describe the present disclosure, parts unrelated to the description are omitted in the drawings, and the same reference numerals are designated to the same or similar elements throughout the specification.

In addition, accompanying drawings are provided only in order to allow embodiments disclosed in the present specification to be easily understood and are not to be interpreted as limiting the technical concept disclosed in the present specification, and it is to be understood that the present disclosure includes all modifications, equivalents, and substitutions without departing from the scope and concept of the present disclosure.

Furthermore, the size and thickness of each element shown in the drawing are arbitrarily shown for convenience of explanation, and present disclosure is not necessarily limited to those shown. In the drawings, the thickness of layers, films, panels, regions, etc., are exaggerated for clarity.

Furthermore, it will be understood that when an element such as a layer, film, region, or substrate is referred to as being “on” another element, it can be directly on the other element or intervening elements may also be present. On the contrary, when an element is referred to as being “directly on” another element, there are no intervening elements present. Furthermore, in the specification, the word “on” or “above” means positioned on or below the object portion and does not necessarily mean positioned on the upper side of the object portion based on a gravitational direction.

Unless explicitly described to the contrary, the word “comprise” and variations such as “comprises” or “comprising” will be understood to imply the inclusion of stated elements but not the exclusion of any other elements.

Furthermore, throughout the specification, “connected” means that two or more elements are not only directly connected, but two or more elements may be connected indirectly through other elements, physically connected as well as being electrically connected, or it may be referred to by different names depending on the location or function but may mean integral.

Hereinafter, embodiments will be described in detail with reference to the drawings.

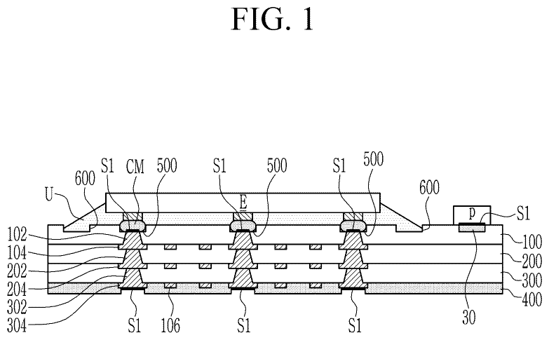

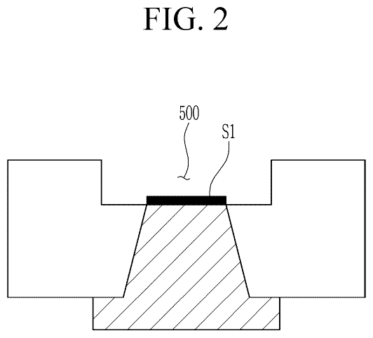

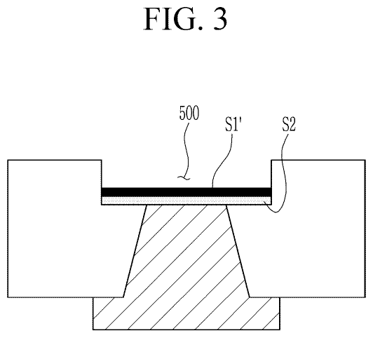

FIG. 1 is a cross-sectional view illustrating a printed circuit board and an electronic component including the same according to an embodiment, and FIG. 2 is a cross-sectional view illustrating a portion of the printed circuit board according to an embodiment. In addition, FIG. 3 is a cross-sectional view illustrating a portion of a printed circuit board according to another embodiment.

Referring to FIG. 1, the electronic component package according to the embodiment may include an electronic component E connected to a printed circuit board through a connection member CM such as solder. The electronic component may be a semiconductor chip. An underfill U is disposed between the printed circuit board and the electronic component E to protect metal members such as the connection member CM and an outer connection pad formed on a surface of the semiconductor chip.

The printed circuit board may include a plurality of insulating layers 100, 200, 300, a circuit wiring 106 and connection pads disposed on the insulating layers 100, 200, 300, and connection vias 202, 302 penetrating one of the insulating layers 100, 200, 300 to connect the connection pads disposed on different insulating layers.

The plurality of insulating layers may include a first outer insulating layer 100, a second outer insulating layer 300, and an inner insulating layer 200 interposed therebetween. Although the inner insulating layer 200 is illustrated as a single layer in FIG. 1, the inner insulating layer 200 may include a plurality of layers according to the design of the printed circuit board. When the inner insulating layer 200 includes a plurality of insulating layers, circuit wirings and connection pads may also be disposed on each insulating layer.

The insulating layers 100, 200, 300 may be an Ajinomoto Build-up Film (ABF). Furthermore, at least a one of the insulating layers 100, 200, 300 may be a prepreg manufactured by impregnating glass fibers with a thermosetting resin or a thermoplastic resin. In some cases, at least one of the insulating layers 100, 200, 300 may be a photo-imageable dielectric (PID).

The connection pads 104, 204, 304 may be a first connection pad 104, a second connection pad 204 and a third connection pad 304 respectively disposed on the first outer insulating layer 100, the inner insulating layer 200, and the second outer insulating layer 300. The first connection pad 104 and the second connection pad 204 may be connected to each other by a first connection via 202 penetrating the inner insulating layer 200. The second connection pad 204 and the third connection pad 304 may be connected to each other by a second connection via 302 penetrating the second outer insulating layer 300.

The first outer insulating layer 100 may be an outermost insulating layer facing the electronic component E, and the second outer insulating layer 300 may be an outermost insulating layer opposite the first outer insulating layer 100. The second outer insulating layer 300 may face a mother board, although not illustrated, on which the electronic component package of the present embodiment is mounted. A solder resist layer 400 exposing the third connection pad 304 may be disposed on the second outer insulating layer 300.

The first outer insulating layer 100 may include a cavity 500 in which a portion of a surface thereof is recessed. The cavity 500 may have a circular or elliptical shape when viewed from above the printed circuit board. A bump via 102 may penetrate the first outer insulating layer 100. An end surface of the bump via 102 may be exposed through the bottom surface of the cavity 500. The bump via 102 may have a reduced cross-sectional area along a height direction from the second outer insulating layer 300 to the first outer insulating layer 100. That is, the cross-sectional area of the end surface of the bump via 102 exposed through the bottom surface of the cavity 500 may be smaller than the cross-sectional area of the other end surface of the bump via 102 opposite to the height direction.

The first connection via 202 and the second connection via 302 may also have a reduced cross-sectional area along the height direction like the bump via 102.

Referring to FIG. 2, in an embodiment, a surface treatment layer S1 may be disposed on the end surface of the bump via 102. The surface treatment layer S1 may be a gold (Au), Electroless Nickel Immersion Gold (ENIG), Electroless Nickel Electroless Palladium Immersion Gold (ENEPIG), or Organic Soldering Preservatives (OSP), but is not limited thereto, and a material that protects the end surface of the bump via 102 exposed to the outside and improves bonding properties with the connection member CM such as solder may be applied without limitation.

Referring to FIG. 3, in another embodiment, a surface conductive layer S2 may be interposed between a surface treatment layer S1′ and the end surface of the bump via 102. The surface conductive layer S2 may cover the end surface of the bump via 102 and extend onto the bottom surface of the cavity 500. The surface treatment layer S1′ may also extend onto the bottom surface of the cavity 500 so as to overlap the surface conductive layer S2. According to the present embodiment, since the surface treatment layer S1′ has a larger area than the surface treatment layer S1 described with reference to FIG. 2, the surface treatment layer S1′ may be more stably connected to an outer connection pad of an electronic component such as a semiconductor chip electrically and physically.

The surface conductive layer S2 may be a metal having an etch selectivity with respect to the bump via. That is, with respect to a specific etchant, the surface conductive layer S2 may be etched, while the bump via 102 may not be etched or may be etched at a very low speed. On the contrary, with respect to another etchant, the bump via 102 may be etched, while the surface conductive layer S2 may not be etched or may be etched at a very low speed. In the present embodiment, when the bump via 102 is copper (Cu), the surface conductive layer S2 may be nickel (Ni).

According to embodiments, the end surface of the bump via 102 may be exposed on the bottom surface of the cavity 500, and the surface treatment layers S1 and S1′ may also be disposed to be accommodated in the cavity 500. Therefore, when the electronic component E is mounted on the surface treatment layers S1, S1′ through the connection member CM such as solder, at least a portion of the solder may be accommodated in the cavity 500. As a result, bridges between adjacent bump vias 102 may be reduced.

In addition, the end surface of the bump via 102 may be exposed on the first outer insulating layer 100, and the bump via 102 may be mostly buried in the first outer insulating layer 100. Therefore, mechanical failures such as fall or breakaway of the bump may be reduced by minimizing the portion of the bump protruding above the first outer insulating layer 100.

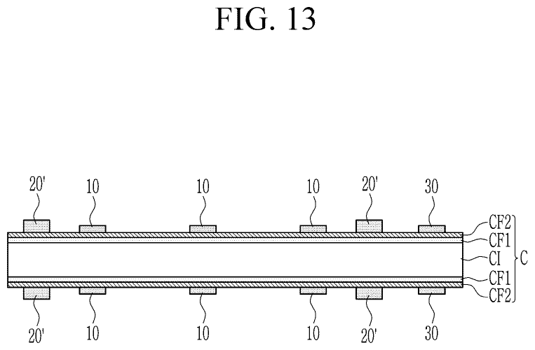

In one embodiment, the first outer insulating layer 100 may include a trench 600 in which a portion different from a portion where the cavity 500 is disposed is recessed. When viewed from above the printed circuit board, the cavity 500 may be disposed in an area in which the electronic component E is mounted, and the trench 600 may be disposed to surround the area in which the electronic component E is mounted. The trench 600 may accommodate a portion of the underfill U to reduce overflow outside the trench 600. The depth of the trench 600 may be greater than the depth of the cavity 500 to accommodate the underfill U. (See FIG. 13) The depths may be measured by an optical microscope or scanning electron microscope. Other methods and/or tools appreciated by one of ordinary skill in the art, even if not described in the present disclosure, may also be used.

In addition, a mounting pad 30 buried so that one surface is exposed on the first outer insulating layer 100 may be disposed in another area of the first outer insulating layer 100. A passive element P such as a multi-layer ceramic capacitor (MLCC) may be mounted on the mounting pad 30. The mounting pad 30 may be made of the same material as the surface conductive layer S2. For example, the mounting pad 30 and the surface conductive layer S2 may be nickel (Ni).

The surface treatment layer S1 may also be disposed on the surface of the mounting pad 30 exposed on the first outer insulating layer 100 and on the surface of the third connection pad 304 exposed by the solder resist layer 400.

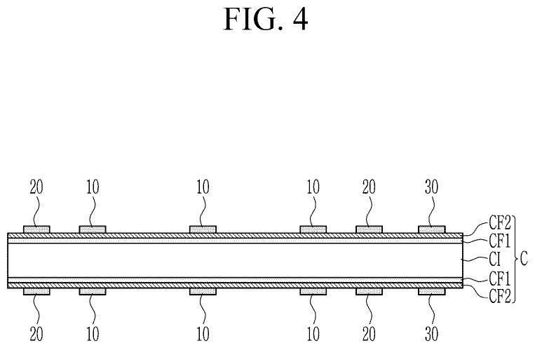

FIGS. 4 to 10 are cross-sectional views illustrating a manufacturing method of a printed circuit board according to an embodiment.

Referring to FIG. 4, a first conductive pattern 10 defining the cavity 500, a second conductive pattern 20 defining the trench 600, and the mounting pad 30 may be formed on a carrier C. As described later, the remaining space after the first conductive pattern 10 is removed may be defined as the cavity 500, and the remaining space after the second conductive pattern 20 is removed may be defined as the trench 600.

The carrier C may include a first copper foil layer CF1 and a second copper foil layer CF2 sequentially stacked on both surfaces of a carrier insulating layer CI. The first conductive pattern 10, the second conductive pattern, and the mounting pad 30 may be formed on the second copper foil layer CF2 through electroplating. That is, the first conductive pattern 10, the second conductive pattern 20, and the mounting pad 30 may be formed by forming a plating mask on the second copper foil layer CF2 by a photolithography process, and electroplating using the second copper foil layer CF2 as a seed layer.

The first conductive pattern 10, the second conductive pattern 20, and the mounting pad 30 may be formed of a metal having an etch selectivity with respect to the second copper foil layer CF2 and the bump via 102 to be formed in a subsequent process. That is, with respect to a specific etchant, the first conductive pattern 10, the second conductive pattern 20, and the mounting pad 30 may be etched, while the second copper foil layer CF2 and the bump via 102 are not etched or may be etched at a very low speed. On the contrary, with respect to another etchant, the second copper foil layer CF2 and the bump via 102 may be etched, while the first conductive pattern 10, the second conductive pattern 20, and the mounting pad 30 may not be etched or may be etched at a very low speed. In the present embodiment, the second copper foil layer CF2 and the bump via 102 may be copper (Cu), and the first conductive pattern 10, the second conductive pattern 20, and the mounting pad 30 may be nickel (Ni).

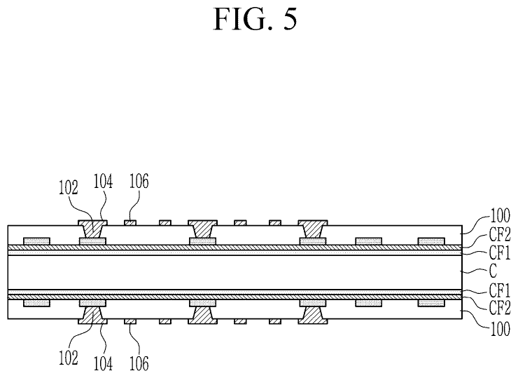

Referring to FIG. 5, the first outer insulating layer 100 may be formed on the second copper foil layer CF2 to cover the first conductive pattern 10, the second conductive pattern 20, and the mounting pad 30. Thereafter, the bump via 102 may be formed to penetrate the first outer insulating layer 100 and to contact the first conductive pattern 10. The first connection pad 104 may be formed to extend from the bump via 102 onto the first outer insulating layer 100. Furthermore, the circuit wiring 106 may be formed on the first outer insulating layer 100.

The bump via 102, the first connection pad 104, and the circuit wiring 106 may be formed through, for example, the following circuit wiring process. That is, a via hole may be formed to penetrate the first outer insulating layer 100 and to expose the first conductive pattern 10 by a drill or laser. Thereafter, a seed layer may be formed on the first outer insulating layer 100 having the via hole and the first conductive pattern 10 exposed through the via hole by electroless plating. Electroplating may be performed after forming a plating mask on the seed layer by a photolithography process. Subsequently, the bump via 102, the first connection pad 104, and the circuit wiring 106 may be formed by removing the plating mask and etching the exposed seed layer. The bump via 102, the first connection pad 104, and the circuit wiring 106 may be formed of copper (Cu). Therefore, the bump via 102 may have an etch selectivity with respect to the first conductive pattern 10 formed of nickel (Ni).

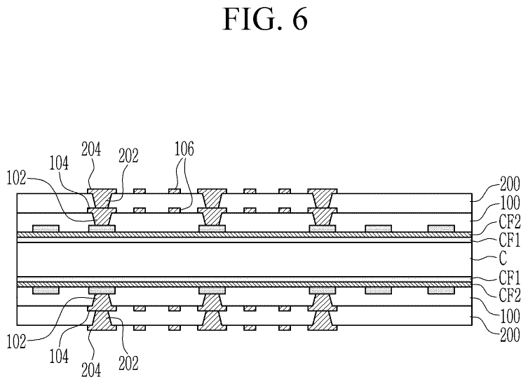

Referring to FIG. 6, by performing a build-up process, the inner insulating layer 200 on the first outer insulating layer 100, the first connection via 202 that penetrates the inner insulating layer 200 and contacts the first connection pad 104, the second connection pad 204 extending from the first connection via 202 onto the inner insulating layer 200, and the circuit wiring 106 may be formed.

The build-up process may refer to repeatedly forming an insulating layer, a via, a pad, and a circuit wiring as described in FIG. 5. Although the inner insulating layer 200 is illustrated as a single layer, the inner insulating layer 200 may include a plurality of layers according to the design of the printed circuit board. When the inner insulating layer 200 includes a plurality of layers, the build-up process may be repeated as many as the number of the plurality of layers.

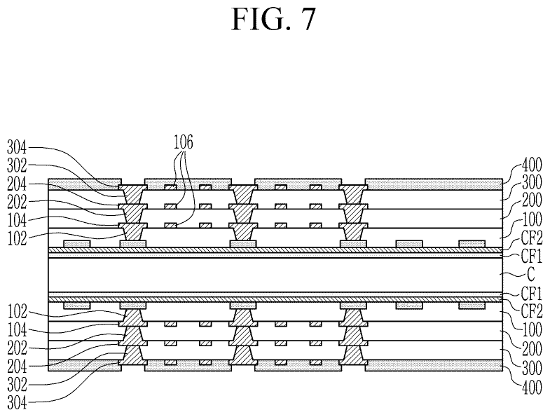

Referring to FIG. 7, the build-up process may be performed to form the second outer insulating layer 300 on the inner insulating layer 200. In addition, the second connection via 302 penetrating the second outer insulating layer 300 to contact the second connection pad 204, the third connection pad 304 extending from the second connection via 302 onto the second outer insulating layer 300, and the circuit wiring 106 may be formed.

Thereafter, the solder resist layer 400 exposing a portion of the third connection pad 304 may be formed on the second outer insulating layer 300. The solder resist layer 400 may be formed by photolithography of a photosensitive resin layer.

In FIGS. 5 to 7, the insulating layers 100, 200, 300 may be an Ajinomoto Build-up Film (ABF). Furthermore, at least a one of the insulating layers 100, 200, 300 may be a prepreg manufactured by impregnating glass fibers with a thermosetting resin or a thermoplastic resin. In some cases, at least one of the insulating layers 100, 200, 300 may be a photo-imageable dielectric (PID). In addition, the connection vias 202, 302, the connection pads 104, 204, 304, and the circuit wirings 106 may be a copper (Cu).

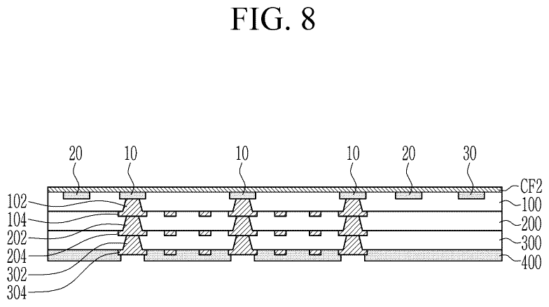

Referring to FIG. 8, the first copper foil layer CF1 and the second copper foil layer CF2 may be separated to remove the remaining portions of the carrier C except for the second copper foil layer CF2. As a result, two coreless stacks may be formed, and hereinafter, one of them will be illustrated and described.

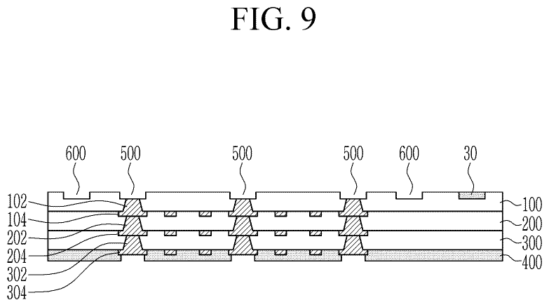

Referring to FIG. 9, the second copper foil layer CF2 may be etched and removed, and then the first conductive pattern 10 and the second conductive pattern 20 may be etched and removed. As a result, the cavity 500 is formed in the space from which the first conductive pattern 10 is removed, and the end surface of the bump via 102 may be exposed on the bottom surface of the cavity 500. Furthermore, the trench 600 may be formed in a space from which the second conductive pattern 20 is removed. Since the first conductive pattern 10 and the second conductive pattern 20 may be formed of a material having an etch selectivity with respect to the bump via 102, loss of the bump via 102 may be minimized while the first conductive pattern 10 and the second conductive pattern 20 are etched.

Meanwhile, while the first conductive pattern 10 and the second conductive pattern 20 are etched, an etching mask is formed on the mounting pad 30 so that the mounting pad 30 may remain.

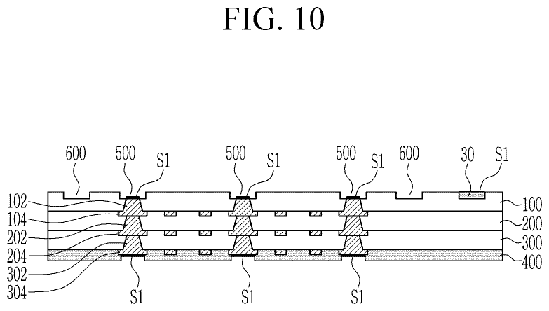

Referring to FIG. 10, the surface treatment layer S1 may be formed on the end surface of the bump via exposed on the bottom surface of the cavity 500. In addition, the surface treatment layer S1 may be formed on the third connection pad 304 and the mounting pad 30. The surface treatment layer S1 may be a gold (Au), Electroless Nickel Immersion Gold (ENIG), Electroless Nickel Electroless Palladium Immersion Gold (ENEPIG), or Organic Soldering Preservatives (OSP), and may be formed through electroplating, electroless plating or coating process.

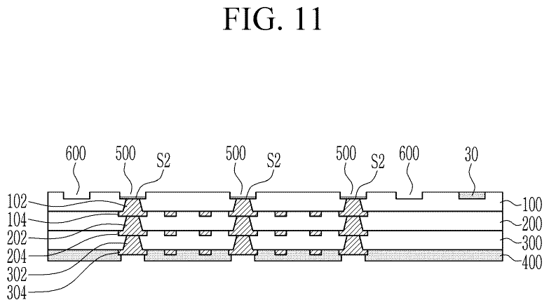

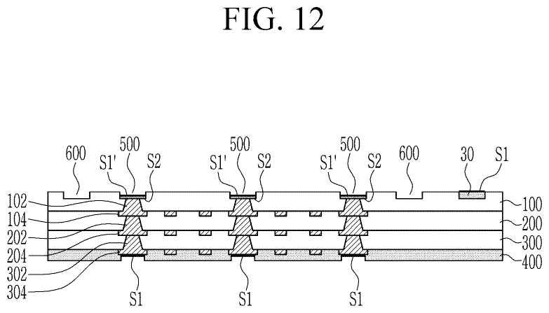

FIGS. 11 to 12 are cross-sectional views illustrating a manufacturing method of a printed circuit board according to another embodiment.

Referring to FIG. 11, the first conductive pattern 10 may not be completely removed, and the thickness thereof is reduced so that the first conductive pattern 10 may remain as the surface conductive layer S2 in the cavity 500. That is, the surface conductive layer S2 may cover the end surface of the bump via 102 and extend onto the bottom surface of the cavity 500. In this case, the surface conductive layer S2 may be formed by the following method. First, an etching mask covering the first conductive pattern 10 and the mounting pad 30 and exposing the second conductive pattern 20 may be formed, and then the second conductive pattern 20 may be etched and removed. As a result, the trench 600 may be formed in the space from which the second conductive pattern is removed. Subsequently, the previously used etching mask may be removed. Then, after forming an etching mask exposing the first conductive pattern 10, the first conductive pattern 10 may be etched to reduce the thickness thereof.

Referring to FIG. 12, the surface treatment layer S1′ may be formed on the surface conductive layer. The surface treatment layer S1′ formed in the cavity 500 may extend onto the bottom surface of the cavity 500 so as to overlap the surface conductive layer S2. The surface treatment layer S1′ may be formed of the same material through the same process as that of the surface treatment layer S1 described with reference to FIG. 10. While the surface treatment layer S1′ is formed, the surface treatment layer S1 may be formed on the mounting pad 30 and on the third connection pad 304 exposed by the solder resist layer 400.

FIG. 13 is a cross-sectional view illustrating a manufacturing method of a printed circuit board according to yet another embodiment.

Referring to FIG. 13, a second conductive pattern 20′ according to the present embodiment may be formed to have a greater thickness than those of the first conductive pattern 10 and the mounting pad 30. The second conductive pattern 20′ may be formed by performing a plating process twice. That is, the first conductive pattern 10, the second conductive pattern 20, and the mounting pad 30 having substantially the same thickness may be formed by performing the first plating process as described in FIG. 4. The etching mask used in the first plating process may be removed. Then, after forming a plating mask covering the first conductive pattern 10 and the mounting pad 30 and exposing the second conductive pattern 20, the second plating process may be performed.

Alternatively, the second conductive pattern 20′ may be formed first by performing the first plating process, and the first conductive pattern 10 and the mounting pad 30 having a thickness smaller than that of the second conductive pattern 20′ may be formed by performing the second plating process.

In the present embodiment, the depth of the trench 600 formed in the space from which the second conductive pattern 20′ is removed may be greater than the depth of the cavity 500 formed in the space from which the first conductive pattern 10 is removed. As the trench 600 is deeper, the underfill U may be accommodated more, thereby further reducing contamination of the printed circuit board due to overflowing underfill.

While embodiments of the present disclosure have been described above, the present disclosure is not limited thereto, and it is possible to perform various modifications within the scope of the claims, the detailed description, and the accompanying drawings, and it is natural that these modifications also fall within the scope of the present disclosure.

What is claimed is:

1. A printed circuit board comprising:
a first outer insulating layer;
a second outer insulating layer;
an inner insulating layer interposing the first outer insulating layer and the second outer insulating layer;
a connection pad and a circuit wiring, wherein the connection pad and the circuit wiring are disposed on the first outer insulating layer, the second outer insulating layer, and the inner insulating layer;
a connection via penetrating one insulating layer among the second outer insulating layer and the inner insulating layer to connect the connection pad disposed on the first outer insulating layer, the second outer insulating layer, and the inner insulating layer; and
a bump via penetrating the first outer insulating layer,
wherein the first outer insulating layer comprises a cavity that is recessed into a first portion of a surface of the first outer insulating layer, and an end surface of the bump via extends from a first surface of the cavity.

2. The printed circuit board of claim 1, further comprising:
a surface treatment layer on the end surface of the bump via.

3. The printed circuit board of claim 1, further comprising:
a surface conductive layer on the end surface of the bump via and the first surface of the cavity; and
a surface treatment layer on the surface conductive layer.

4. The printed circuit board of claim 3, wherein:
the surface conductive layer comprises a metal having an etch selectivity with respect to the bump via.

5. The printed circuit board of claim 2, further comprising:
a trench that is recessed into a second portion of the surface of the first outer insulating layer.

6. The printed circuit board of claim 5, wherein:
a depth of the trench is greater than a depth of the cavity.

7. The printed circuit board of claim 2, further comprising:
a mounting pad buried in the first outer insulating layer,
wherein a surface of the mounting pad extends from the surface of the first outer insulating layer.

8. The printed circuit board of claim 7, further comprising:
a surface conductive layer between the surface treatment layer and the end surface of the bump via,
wherein the connection pad and the surface conductive layer comprise the same material.

9. A printed circuit board comprising:
an insulating layer having a cavity that is recessed into a portion of a surface of the insulating layer;
a bump via penetrating the insulating layer, wherein an end surface of the bump via extends from a surface of the cavity; and
a surface treatment layer on the end surface of the bump via.

10. A manufacturing method of a printed circuit board, comprising:
forming a first conductive pattern defining a cavity on a carrier,
forming a first outer insulating layer on the carrier to cover the first conductive pattern,
forming a bump via penetrating the first outer insulating layer to connect the first conductive pattern and a first connection pad extending from the bump via onto the first outer insulating layer,
applying a build-up process on the first outer insulating layer,
removing the carrier, and
removing at least a portion of the first conductive pattern.

11. The manufacturing method of claim 10, wherein:
the removing of the at least the portion of the first conductive pattern comprises forming the cavity exposing an end surface of the bump via.

12. The manufacturing method of claim 11, further comprising:
forming a surface treatment layer on the end surface of the bump via exposed through a surface of the cavity.

13. The manufacturing method of claim 10, wherein:
the removing of the at least the portion of the first conductive pattern comprises reducing a thickness of the first conductive pattern to form a surface conductive layer remaining in the cavity.

14. The manufacturing method of claim 13, further comprising:
forming a surface treatment layer on the surface conductive layer.

15. The manufacturing method of claim 10, wherein:
the forming of the first conductive pattern further comprises forming a second conductive pattern defining a trench, and
the removing of the at least the portion of the first conductive pattern comprises removing the second conductive pattern.

16. The manufacturing method of claim 10, wherein:
the forming of the first conductive pattern further comprises forming a mounting pad on the carrier.

17. The manufacturing method of claim 10, wherein
the applying of the build-up process on the first outer insulating layer comprises:
forming an inner insulating layer on the first outer insulating layer to cover the first connection pad;
forming a first connection via penetrating the inner insulating layer to connect the first connection pad and a second connection pad extending from the first connection via onto the first outer insulating layer;
forming a second outer insulating layer on the inner insulating layer to cover the second connection pad; and
forming a second connection via penetrating the second outer insulating layer to connect the second connection pad and a third connection pad extending from the second connection via onto the inner insulating layer.

18. An electronic component package, comprising:
a printed circuit board comprising
a first outer insulating layer,
a second outer insulating layer,
an inner insulating layer interposing the first outer insulating layer and the second outer insulating layer,
a connection pad and a circuit wiring, wherein the connection pad and the circuit wiring are disposed on the first outer insulating layer, the second outer insulating layer, and the inner insulating layer,
a connection via penetrating one insulating layer among the second outer insulating layer and the inner insulating layer to connect the connection pad disposed on the first outer insulating layer, the second outer insulating layer, and the inner insulating layer,
a cavity that is recessed into a portion of a surface of the first outer insulating layer,
a bump via penetrating the first outer insulating layer so that an end surface of the bump via extends from a surface of the cavity, and
a surface treatment layer on the end surface of the bump via,
a semiconductor chip comprising an outer connection pad on one surface of the semiconductor chip; and
a connection member, wherein at least a portion of the connection member is disposed within the cavity, and the connection member connects the end surface of the bump via to the outer connection pad of the semiconductor chip.

19. An electronic component package of claim 18, further comprising:
a surface conductive layer interposing the end surface of the bump via and the surface treatment layer, and extending onto a surface of the cavity.

20. An electronic component package of claim 19, wherein:
the surface conductive layer comprises a metal having an etch selectivity with respect to the bump via.
